(19) United States
(12) Patent Application Publication
(10) Pub. No.: US 2008/0179079 A1
(43) Pub. Date: Jul. 31, 2008

(54) Printed-Wiring Board, Bending Processing Method for Printed-Wiring Board, and Electronic Equipment

(75) Inventors: Norihiro Ishii, Akishima-shi (JP); Sadahiro Tamai, Ome-shi (JP); Terunari Kano, Hamura-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 11/923,487

(22) Filed: Oct. 24, 2007

(30) Foreign Application Priority Data
Oct. 30, 2006 (JP) 2006-294619

(51) Int. Cl. H05K 1/03; H05K 3/00

(52) U.S. Cl. 174/254; 29/825

(57) ABSTRACT

According to one embodiment, there is provided a printed-wiring board in which a composite board is formed to have rigid portions and a bending portion, wherein the bending portion includes linear protrusions each formed with solder resist having a bending resistance property.

### CROSS-REFERENCE TO RELATED APPLICATIONS

This application is based upon and claims the benefit of priority from Japanese Patent Application No. 2006-294619, filed Oct. 30, 2006, the entire contents of which are incorporated herein by reference.

### BACKGROUND

1. Field

One embodiment of the present invention relates to a printed-wiring board in which rigid board portions and a bending portion are formed in a laminated board.

2. Description of the Related Art

A technique that allows a portion of a rigid printed-wiring board to have a bending property is one which forms a bending portion between rigid boards by interposing an insulating layer made of a flexible insulating material between the rigid boards and integrating the rigid boards with the insulating layer interposed therebetween. This technique is implemented by using a polyimide-based insulating material, which is used as an FPC base material, as the flexible insulating material.

However, the polyimide-based material is high in water absorption and therefore subject to variations in shape and electrical characteristic due to moisture absorption. When mounting parts on the board made of the polyimide-based material, a baking process is required prior to mounting of the parts. In addition, the polyimide-based material is expensive. Therefore, the use of the polyimide-based material causes many manufacturing problems. Accordingly, a board manufacturing technique has been devised which allows a rigid board to have a bending property by partially scraping off to reduce the thickness of that portion so that the scraped portion of the rigid board may have the bending property. For example, in a printed-wiring board in which two or more insulating layers are stacked, partially peeling off one of the insulating layers to expose a surface of a second insulating layer at which a thin portion or a bending portion is formed in the printed-wiring board. In this case, however, the surface of the peeled-off portion may have irregularities and stress at the time of bending will be concentrated in the thin portion, causing the bending portion of the wiring board to be damaged. Furthermore, this type of printed-wiring board has confirmed that cracks tends to develop in the bending portion at the boundary between the bending and rigid portions when a torsional stress is applied to the bending portion, for example, in a manufacturing step in which the wiring board is handled.

As a technique to avoid such cracks caused by forming the thin portion in the printed-wiring board, a prior art technique exists which forms a wiring circuit on one surface of a flexible board and a dummy wiring pattern on its other surface to thereby allow it to have a reasonable bending property. An example of such a technique is described in, for example, JP-A 2005-294639 (KOKAI).

According to one aspect of the present invention, there is provided a printed-wiring board including a base board having rigid portions and a bending portion wherein on both sides of the bending portion a plurality of linear protrusions each formed of a solder resist so that the linear protrusions constitute a bending resistance portion.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a sectional side view of a printed-wiring board according to an embodiment of the invention, cut along a line I-I and seen in the arrow as shown in FIG. 2;

FIG. 2 is a plan view of the printed-wiring board shown in FIG. 1;

FIG. 3 shows an example of the bent state of the printed-wiring board of the embodiment;

FIG. 4 shows another example of the bent state of the printed-wiring board of the embodiment;

FIG. 5 is a sectional view of the printed-wiring board of the embodiment at a step for manufacturing the printed-wiring board;

FIG. 6 is a sectional view of the printed-wiring board of the embodiment at a step subsequent to the step shown in FIG. 5;

FIG. 7 is a sectional view of the printed-wiring board of the embodiment at a step subsequent to the step shown in FIG. 6;

FIG. 8 is a sectional view of the printed-wiring board of the embodiment at a step subsequent to the step shown in FIG. 7;

FIG. 9 is a sectional view of the printed-wiring board of the embodiment at a step subsequent to the step shown in FIG. 8;

FIG. 10 is a sectional view of the printed-wiring board of the embodiment at a step subsequent to the step shown in FIG. 9;

FIG. 11 is a sectional view of the printed-wiring board of the embodiment at a step subsequent to the step shown in FIG. 10;

FIG. 12 shows another arrangement of the linear protrusions formed on the bending portion of a printed-wiring board according to another embodiment of the present invention;

FIG. 13 shows an example of the bent state of the printed-wiring board shown in FIG. 12; and

FIG. 14 is a sectional side view of an electronic equipment which has a printed-wiring board manufactured according to the present invention and built therein.

### DETAILED DESCRIPTION

Various embodiments according to the invention will be described hereinafter with reference to the accompanying drawings.

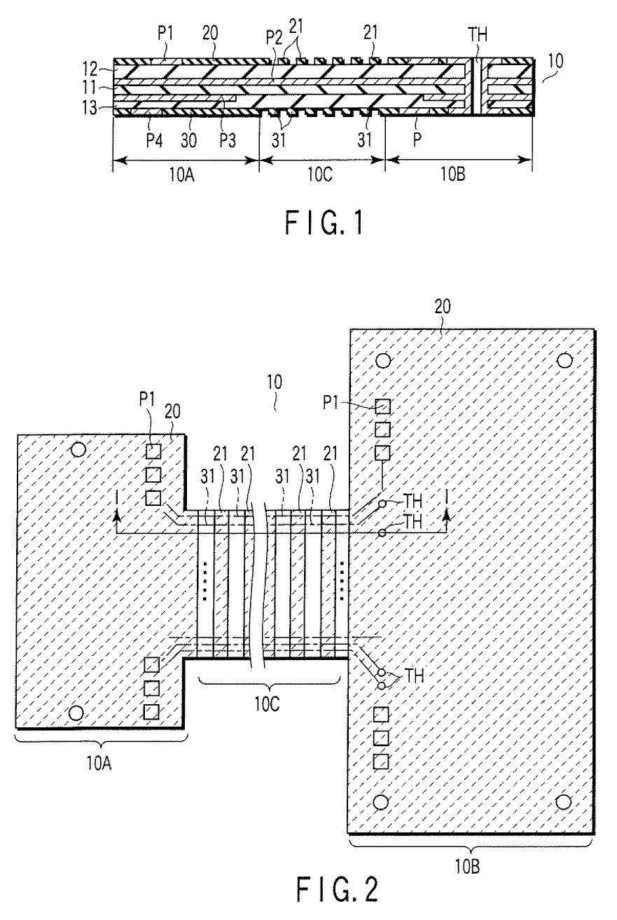

An embodiment of the present invention will be described hereinafter with reference to the accompanying drawings. A configuration of the printed-wiring board according to the embodiment of the invention is shown in FIGS. 1 and 2. This printed-wiring board shown in FIGS. 1 and 2 takes, as an example, a structure such that three layers of insulating material are stacked to form a composite or laminated board with four wiring layers so that the printed-wiring board is configured to have two rigid portions 10A, 10B and a bending portion 10C interposed between the rigid portions 10A and 10B.

The printed-wiring board of the embodiment is configured, as shown in FIG. 1, such that a composite or laminated board 10, which is formed with four wiring layers P1, P2, P3 and P4 each formed of a copper or aluminum film and three flexible layers 11, 12 and 13 each formed of an insulating material, has two rigid portions 10A and 10B and a bending portion 10C interposed between the rigid portions.

The rigid portions 10A and 10B are formed, as shown in FIGS. 1 and 2, by coating the first and second surfaces of the composite board 10 formed by stacking the three flexible insulating boards 11, 12 and 13 with layers 20 and 30 of solder resist.

In the rigid portions 10A and 10B, each of the wiring layers P1 to P4 is formed, and a through-hole connector (TH) is formed to connect the wiring layers P1 to P4, selectively. In FIG. 1, the through-hole connector TH is illustrated only in the rigid portion 10B and one or more through-hole connectors may be made in the rigid portion 10A and/or 10B. In addition, the rigid portions 10A and 10B have circuit patterns formed in their respective wiring layers P1 to P4 including the first and second surfaces of the composite board 10.

The bending portion 10C is formed by removing (peeling off) wiring layers or copper films P1 and P4 from the first and second surfaces of that region of the composite board 10 where the bending portion is to be formed.

Furthermore, the bending portion 10C is formed on its first and second surfaces with linear protrusions 21 and 31, respectively, which are made by partially cutting off the solder resist layers 20 and 30 linearly. In the embodiment shown in FIG. 1, six linear protrusions 21 are formed in the solder resist layer 20 on the first surface of the board 10 and six linear protrusions 31 are formed in the solder resist layer 30 on the second surface of the board 10. The linear protrusions 21 and 31 are arranged at regular intervals on the first and second surfaces of the board 10, respectively, in such a way that each of the linear protrusions 21 on the first surface is not opposed to each of the linear protrusions 31 on the second surface thereof. Namely, the linear protrusions 21 and 31 are staggered with each other.

The linear protrusions 21 and 31 are formed when the solder resist layers 20 and 30 are formed on the rigid portions 10A and 10B. The linear protrusions 21 and 31 are partially hardened at the bending portion 10C where the protrusions 21 and 31 are formed. The manufacturing process for forming the linear protrusions 21 and 31 will be described in detail later.

The linear protrusions 21 and 31 are hardened to form a bending resistance portion to protect the bending portion 10C from cracks due to application thereto of external torsional stress with respect to the rigid portions 10A and 10B.

Furthermore, the linear protrusions 21 and 31 also acts as a bending direction control means to control the direction of bending when they are arranged parallel to the predetermined bending direction.

By the linear protrusions 21 and 31, which constitute the bending resistance portion and the bending direction control means, the bending portion 10C is made easy to bend in the bending direction but difficult to bend in the torsional direction. Thereby, cracks can be prevented from developing in the bending portion at the time of bending to improve the yield. Furthermore, handling at work can be facilitated to increase the working efficiency.

If the bending portion 10C were not formed with the linear protrusions 21 and 31, it would be easy to bend in the torsional direction when subjected to an external torsional stress and cracks would develop in the edges of the bending portion 10C when it undergoes a bending stress in the torsional direction as it is without resistance.

When the linear protrusions 21 and 31 are formed on the bending portion 10C, they can resist bending stress in the torsional direction and act to prevent bending in the torsional direction. Thereby, cracks can be prevented from developing in the bending portion 10C at the time of bending, thus improving the yield.

Moreover, by arranging the linear protrusions 21 and 31 parallel to the predetermined direction of bending, the bending portion 10C is made to resist bending in a direction different from the predetermined bending direction but can be bent without resistance in the predetermined bending direction. In this case, the bending portion 10C can be bent at even angles of bending so that bending is not biased (bending is not concentrated on a particular part of the bending portion). Thereby, handing at work can be facilitated to increase the working efficiency.

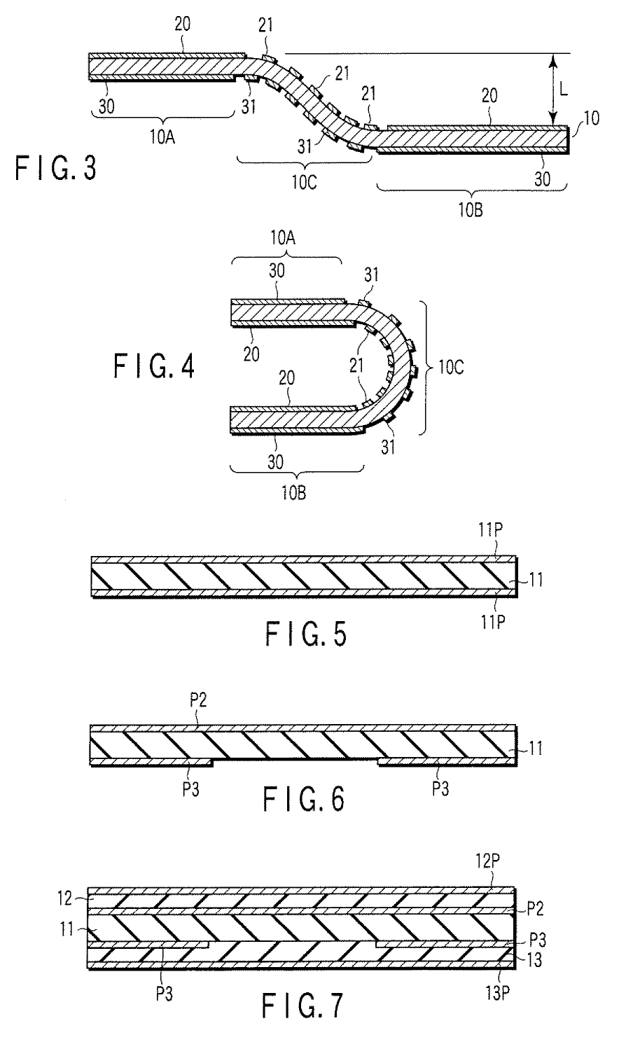

FIGS. 3 and 4 show examples of bent states of the bending portion 10C.

FIG. 3 shows the bent state of the bending portion 10C when the rigid portions 10A and 10B are mounted in parallel with each other with a difference in level L therebetween. In such a case, the bending portion 10C tends to undergo external stress in the torsional direction at the time of mounting. Therefore, when the bending portion 10C is not formed with the linear protrusions 21 and 31, the external stress is directly applied to the edges of the bending portion 10C, making cracks easy to develop in the bending portion 10C. In this embodiment, however, the bending portion 10C is formed with the linear protrusions 21 and 31, and accordingly, the linear protrusions 21 and 31 can resist bending stress in the torsional direction and act to prevent bending in the torsional direction. Moreover, since the linear protrusions 21 and 31 are arranged evenly and in parallel to the predetermined direction of bending, the bending portion 10C can be bent without resistance in the predetermined bending direction and moreover at even angles of bending.

FIG. 4 shows another bent state of the bending portion 10C when it is bent into the shape of the letter U. In such a case, as in the case shown in FIG. 3, the linear protrusions 21 and 31 act to prevent the bending portion 10C from bending in the torsional direction and the bending portion 10C can be bent in the bending direction without resistance at even angles of bending.

The manufacturing steps of the above-mentioned printed-wiring board of the embodiment are shown in FIG. 5 to FIG. 11.

In step 1 shown in FIG. 5, the flexible board 11 is processed which forms the core insulation material layer as an inner layer of the composite board 10 shown in FIG. 1. For example, a prepreg material layer with flexibility is prepared and on both sides thereof are formed electro-conducting layers 11P of copper film to thereby fabricate the flexible board 11.

In step 2 shown in FIG. 6, the conducting layers 11p formed on the sides of the flexible board 11 are etched to form wiring layers P2 and P3 of circuit patterns as inner-layer circuit patterns.

In step 3 shown in FIG. 7, the insulation flexible boards 12 and 13 are stacked to the first and second surfaces of the flexible board 11 formed with the wiring layers P2 and P3 to form the top and bottom layers of the composite board 10. For example, the flexible boards 12 and 13 are each formed of an RCC (resin coated copper foil) material with copper films 12P and 13P but with no glass fiber. Thereby, the flexible boards 12 and 13 are stacked on top and bottom surface of the board 11 with conducting layers 12p and 13p, respectively.

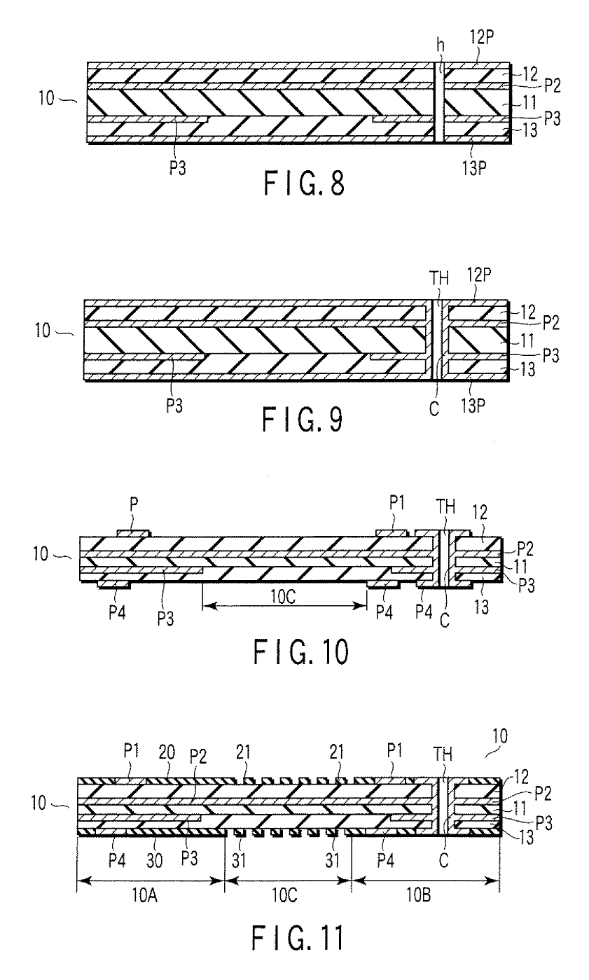

In step 4 shown in FIG. 8, the stacked flexible boards 11, 12 and 13 are drilled to form a through-hole h or a via hole.

In step 5 shown in FIG. 9, the drilled inner wall portion of the hole h is plated with copper, for example, to form the through-hole (TH) connector C for connecting the given portions of the wiring layers 12P, P2, P3 and 13P together. A via (not shown) may be formed in the similar manner in the board 10.

In step 6 shown in FIG. 10, the surfaces of the stacked flexible boards 11 and 13 are subjected to an etching process. This etching process entirely removes the conductive wiring layers 12p and 13p in a region of the composite board 10 where the bending portion 10C is to be formed.

Then, in step 7 shown in FIG. 11, solder resist layers 20 and 30 are coated onto the whole top and bottom surfaces of the board 10. Then, the solder resist layers applied to those regions of the surfaces of the composite board where the rigid portions 10A and 10B are to be formed remained, and those regions of the solder resist layers 20 and 30 applied to the top and bottom surfaces of the bent portion 10C are subjected to be etched partially to form the linear protrusions 21 and 31 using a known lithography method, for example. In the etching process, the solder resist is hardened by a known hardening method such as that using a violet ray while applying heat thereto.

Thus, the printed-wiring board shown in FIG. 1 is manufactured which has the rigid portions 10A and 10B coated with the solder resist layers 20 and 30 and the bending portion 10C formed with the linear protrusions 21 and 31.

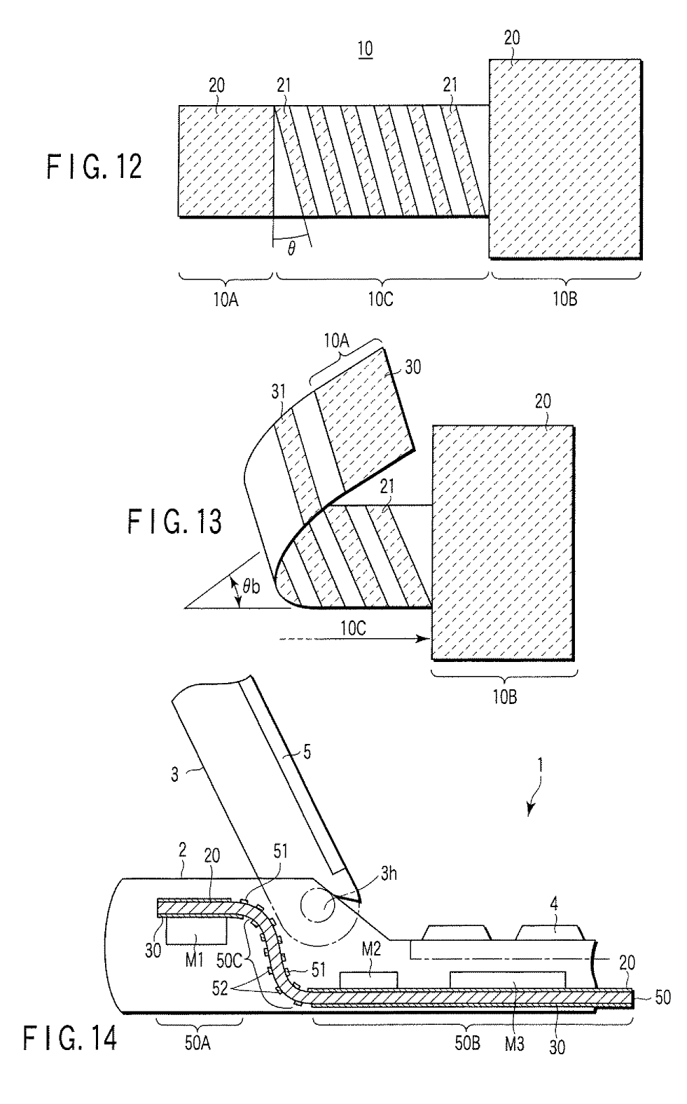

In the above embodiment, the bending portion 10C is formed with the linear protrusions 21 and 31 parallel to the direction of its width between the rigid portions 10A and 10B, so that the rigid portions 10A and 10B may be overlapped when the bent portion 10C is bent in the letter U as shown in FIG. 4. As shown in FIGS. 12 and 13, however, in another embodiment of the present invention, the linear protrusions may be formed at a predetermined angle θ of inclination with respect to the direction of width of the bending portion 10C. By so doing, the bending portion 10C can be easily bent into the shape of the letter U at the given angle θ of inclination, so that the rigid portions 10A and 10B are bent in the given direction as shown in FIG. 13. In the case of the embodiment of FIGS. 12 and 13, if the bent portion 10C is bent in a state as shown in the case of FIG. 4, a tortional stress will be applied to the bent portion 10C. When the board 10 shown in the embodiment of FIG. 12 is bent in the similar manner as in the case of the bent state shown in FIG. 3, the rigid portions 10A and 10B may be positioned at the different level L while the rigid portions 10A and 10B are offset in the width direction of the bent portion 10C.

In such an example of bending, as in the example shown in FIG. 4, the bending portion 10C can be structured such that it is easy to bend in the predetermined bending direction at the given angle θb but difficult to bend in the width direction of the bent portion 10C due to the tortional resistance function of the linear protrusions 21 and 31 inclined by θ as shown in FIG. 12. That is, the linear protrusions 21 and 31 act to prevent the bending portion 10C from bending in the torsional direction, and the bending portion 10C can be bent in the bending direction without resistance at even angles of bending in the similar manner as in the case of FIGS. 1 and 2.

FIG. 14 shows the configuration of electronic equipment in which the printed-wiring board 50 prepared in the similar manner as the embodiments according to the present invention is mounted. Here, the printed-wiring board 50 may be manufactured in accordance with the manufacturing steps shown in FIGS. 5 through 11 and is applicable to a small-sized portable computer or the like.

In FIG. 14, a display unit casing 3 is swingably mounted to the main body 2 of the portable computer 1 by a hinge mechanism 3h. The main body 2 is equipped with operation units, such as a pointing device, a keyboard 4, etc. The display unit casing 3 has a display device 5, such as an LCD, built in.

In addition, the main body 2 is equipped with a printed circuit board (mother board) which has various control circuits M1, M2 and M3 for controlling, for example, the keyboard 4 and the display device 5 mounted on the printed-wiring board 50 which has rigid portions 50A and 50B coated with solder resist layers 20 and 30 and a bending portion 50C with linear protrusions 51 and 52 of solder resist, manufactured in accordance with the manufacturing steps shown in FIGS. 5 through 11.

The printed-wiring board 50 is structured such that the bending portion 50C is easy to bend in the bending direction but difficult to bend in the torsional direction owing to the bending resistance portion and bending direction control means based on the linear protrusions 51 and 52. Thereby, the bending portion 50C can be bent easily without developing cracks therein, thus improving the yield. In addition, the bending portion 50C can be bent at even angles of bending with no bending concentrated only on a particular part. This allows handling at work to be facilitated and working efficiency to be improved.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed-wiring board comprising a composite board having rigid portions and a bending portion, wherein the bending portion includes linear protrusions each formed with solder resist having a bending resistance property.

2. The printed-wiring board according to claim 1, wherein the linear protrusions are arranged parallel to the bending direction and used as means to control the bending direction.

3. The printed-wiring board according to claim 2, wherein the linear protrusions are formed on both surfaces of the bending portion.

4. The printed-wiring board according to claim 3, wherein the linear protrusions are formed on both surfaces of the bending portion so that the linear protrusions on one surface of the bending portion are not opposite to those on the other surface.

5. The printed-wiring board according to claim 1, wherein the composite board is formed by stacking a plurality of insulating flexible boards containing a prepreg material.

6. The printed-wiring board according to claim 1, wherein the bending portion is formed by peeling off partially a copper film from the surface of a region of the composite board where the bending portion is to be formed.

7. The printed-wiring board according to claim 1, wherein the rigid portions are formed by coating the surfaces of regions of the composite board where the rigid portions are to be formed with a layer of solder resist.

8. The printed-wiring board according to claim 1, wherein the rigid portions are set at both ends of the bending portion, and a wiring pattern is formed on a surface of an inner layer formed in the bending portion to interconnect the rigid portions.

9. The printed-wiring board according to claim 1, wherein the linear protrusions are formed to have a given angle of inclination with respect to the direction of width of the bending portion and be parallel to one another.

10. A printed-wiring board processing method to form rigid portions and a bending portion in a composite board, comprising the steps of:
peeling off an electro-conductive film from the surface of a region of the composite board where the bending portion is to be formed;
coating the surfaces of regions of the composite board where the rigid portions are to be formed with layers of the solder resist; and
forming linear protrusions made of the solder resist on the surfaces of a region of the composite board where the bending portion is to be formed, the linear protrusions acting bending resistance portions.

11. The printed-wiring board processing method according to claim 10, wherein the linear protrusions are arranged parallel to the direction of bending to form bending direction control means to control the direction of bending.

12. The printed-wiring board processing method according to claim 11, wherein the linear protrusions are formed on both surfaces of a region of the composite board where the bending portion is to be formed.

13. The printed-wiring board processing method according to claim 12, wherein each of the linear protrusions on one surface of that region is not opposed to each of those on the other surface.

14. The printed-wiring board processing method according to claim 10, wherein the rigid portions are set at both ends of the bending portion, and an interconnection pattern is formed on a surface of an inner layer included in the bending portion to interconnect the rigid portions.

15. The printed-wiring board processing method according to claim 12, wherein the linear protrusions are formed to have a given angle of inclination with respect to the direction of width of the bending portion and be parallel to one another.

16. An electronic equipment having a printed-wiring board with integrally formed rigid and bending portions, wherein the wiring board has bending resistance portions on the surface of the bending portion, and the bending resistance portions are formed of linear protrusions each made of solder resist.

17. The electronic equipment according to claim 16, wherein the bending resistance portion is set parallel to the direction of bending to form a member to control the direction of bending.

18. The electronic equipment according to claim 17, wherein the linear protrusions are formed on both surfaces of the bending portion so that the bending portion becomes easy to bend in the direction of bending but difficult to bend in the torsional direction.
